(19) United States
(12) Patent Application Publication
(10) Pub. No.: US 2025/0328078 A1
(43) Pub. Date: Oct. 23, 2025

(54) DEVELOPER SUPPLY EQUIPMENT

(71) Applicant: Samsung Electronics Co., Ltd., Suwon-si (KR)

(72) Inventors: Youngho HWANG, Suwon-si (KR); Sunyoung YUN, Suwon-si (KR); Jaehong LIM, Suwon-si (KR); Chulmin CHO, Suwon-si (KR)

(73) Assignee: Samsung Electronics Co., Ltd., Suwon-si (KR)

(21) Appl. No.: 18/974,907

(22) Filed: Dec. 10, 2024

(30) Foreign Application Priority Data
Apr. 17, 2024 (KR) 10-2024-0051560

(51) Int. Cl. G03F 7/30; H01L 21/67

(52) U.S. Cl. CPC G03F 7/3028; H01L 21/6715

(57) ABSTRACT

Example embodiments are directed to a developer supply device including a first pipe supply a developer of a first temperature, a second pipe supply the developer of a second temperature, a mixer fluidly connected to the first pipe and the second pipe and mix the developer to obtain a mixed developer, a first flow rate controller control a flow rate of the developer into the mixer, a second flow rate controller control a flow rate of the developer into the mixer, a nozzle to dispense the mixed developer on a target substrate, a third pipe fluidly connected to the mixer and the nozzle to supply the mixed developer; a temperature sensor to measure a temperature of the mixed developer, and a controller to control the first flow rate controller or the second flow rate controller based on the temperature.

### CROSS-REFERENCE TO RELATED APPLICATION

This application claims priority under 35 U.S.C. § 119 to Korean Patent Application No. 10-2024-0051560 filed in the Korean Intellectual Property Office on Apr. 17, 2024, the entire contents of which are incorporated herein by reference.

### BACKGROUND

Example embodiments relate to a developer supply device. A photolithography process used in a semiconductor manufacturing involves coating a photoresist (PR) on a target substrate, such as a wafer, and patterning the photoresist by an exposing and developing. The development of the photoresist may be performed by removing the photoresist by dispensing a developer on the wafer on which the photoresist is coated.

Since the pattern of the photoresist is sensitive to the temperature of the developer, it is necessary to precisely control the temperature of the developer dispensed on the wafer. For example, the temperature of the developer may affect the critical dimension (CD) of the pattern, a line edge roughness (LER), and an angle between the pattern and the target substrate, which may be factors in controlling the exposure dose of the preceding process. Additionally, the optimal developer temperature for the photoresist development may vary depending on the type of the photoresist.

### SUMMARY

According to some example embodiments, a developer supply device includes a first pipe configured to supply a developer having a first temperature, a second pipe configured to supply the developer having a second temperature lower than the first temperature, a mixer fluidly connected to the first pipe and the second pipe and configured to mix the developer having the first temperature and the developer having the second temperature to obtain a mixed developer, a first flow rate controller configured to control a flow rate of the developer having the first temperature flowing into the mixer, a second flow rate controller configured to control a flow rate of the developer having the second temperature flowing into the mixer, a nozzle configured to dispense the mixed developer from the mixer on a target substrate, a third pipe fluidly connected to the mixer and the nozzle and configured to supply the mixed developer from the mixer to the nozzle, a temperature sensor configured to measure a temperature of the mixed developer, and a controller configured to control at least one of the first flow rate controller and the second flow rate controller based on the temperature of the mixed developer measured by the temperature sensor.

According to some example embodiments, a developer supply device including a first pipe configured to supply a developer having a first temperature, the first pipe including a first inner pipe through which the developer flows and a first outer pipe positioned concentric with the first inner pipe and through which a first fluid flows, a second pipe configured to supply a developer having a second temperature lower than the first temperature, the second pipe including a second inner pipe through which the developer flows and a second outer pipe positioned concentric with the second inner pipe and through which a second fluid having a temperature lower than the first fluid flows, a mixer fluidly connected to the first pipe and the second pipe and configured to mix the developer having the first temperature and the developer having the second temperature to obtain a mixed developer, a first flow rate controller configured to control a flow rate of the developer having the first temperature flowing into the mixer, a second flow rate controller configured to control a flow rate of the developer having the second temperature flowing into the mixer, a nozzle configured to dispense the mixed developer from the mixer on a target substrate, a third pipe fluidly connected to the mixer and the nozzle, and configured to supply the mixed developer from the mixer to the nozzle, a first temperature sensor configured to measure a temperature of the mixed developer, and a controller configured to control at least one of the first flow rate controller and the second flow rate controller based on the temperature of the mixed developer measured by the first temperature sensor.

According to some example embodiments, a developer supply device includes a developer storage container configured to store a developer, a first pipe configured to change a temperature of the developer and configured to supply the developer having a first temperature, a second pipe configured to change the temperature of the developer and configured to supply the developer having a second temperature lower than the first temperature, a third pipe fluidly connected to the developer storage container, the first pipe and the second pipe, and configured to supply the developer from the developer storage container to the first pipe and the second pipe, a mixer fluidly connected to the first pipe and the second pipe and configured to mix the developer having the first temperature and the developer having the second temperature to obtain a mixed developer, a first flow rate controller configured to control a flow rate of the developer having the first temperature flowing into the mixer, a second flow rate controller configured to control a flow rate of the developer having the second temperature flowing into the mixer, a nozzle configured to dispense the mixed developer provided from the mixer on a target substrate, a fourth pipe connected to the mixer and the nozzle and configured to supply the mixed developer from the mixer to the nozzle, a fifth pipe connected to the fourth pipe and the third pipe, and configured to supply the mixed developer from the fourth pipe to the third pipe when the mixed developer is not dispensed, a temperature sensor configured to measure a temperature of the mixed developer, and a controller configured to control of at least one of the first flow rate controller and the second flow rate controller based on the temperature of the mixed developer measured by the temperature sensor. When the mixed developer is not being dispensed, the fifth pipe, the third pipe, the first pipe, the second pipe and the fourth pipe are configured to circulate the mixed developer.

### BRIEF DESCRIPTION OF THE DRAWINGS

The above and other aspects, features and other advantages of the example embodiments will be more clearly understood from the following detailed description, taken in conjunction with the accompanying drawings.

FIG. 1 illustrates a developer supply device, according to some example embodiments.

FIGS. 2a and 2b are cross-sectional views of the second pipe and the third pipe of the developer supply device of FIG. 1, according to some example embodiments.

FIG. 3 illustrates the first temperature sensor included in the developer supply device of FIG. 1, according to some example embodiments.

FIG. 4 illustrates the first temperature sensor included in the developer supply device of FIG. 1, according to some example embodiments.

FIG. 5 illustrates a developer supply device, according to some example embodiments.

FIG. 6 illustrates a developer supply device, according to some example embodiments.

FIG. 7 illustrates a developer flow path in the developer supply device of FIG. 6 when dispensing the mixed developer, according to some example embodiments.

FIG. 8 illustrates a developer flow path in the developer supply device of FIG. 6 when mixed developer is not being dispensed, according to some example embodiments.

FIG. 9 illustrates a developer supply device, according to some example embodiments.

FIG. 10 illustrates a mixer of the developer supply devices of FIGS. 1, 5, 6, and 9, according to some example embodiments.

### DETAILED DESCRIPTION

The size and thickness of each component illustrated in the drawings are arbitrarily shown for understanding and ease of description, but example embodiments are not limited thereto. Thicknesses of several portions and regions are enlarged for clear expressions. In the drawings, the thickness of layers, films, panels, regions, etc., are exaggerated for clarity. In the drawings, for understanding and ease of description, the thickness of some layers and areas is exaggerated.

In the specification and the claims that follow, when it is described that an element is “coupled” to another element, the element may be “directly coupled” to the other element or “electrically coupled” to the other element through a third element.

In addition, unless explicitly described to the contrary, the word “comprise”, and variations such as “comprises” or “comprising”, will be understood to imply the inclusion of stated elements but not the exclusion of any other elements.

In the specification, the terms “high temperature” and “low temperature” are used to distinguish the relative differences between these temperatures and are not used to limit it to a specific temperature range.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Additionally, throughout the specification, references to any component in the singular include references to the plurality of these components, unless specifically stated to the contrary.

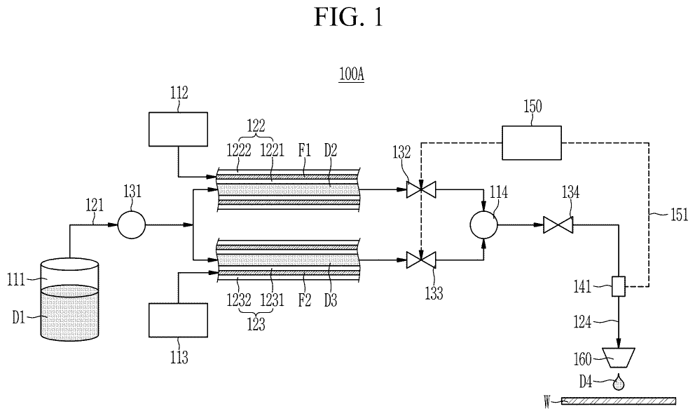

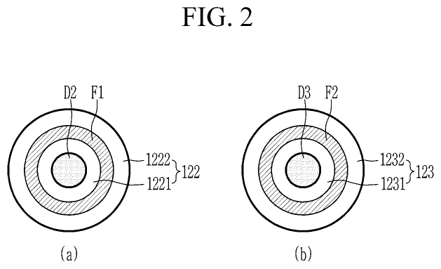

FIG. 1 is a schematic diagram of a developer supply device 100A, according to some example embodiments. FIGS. 2a and 2b are cross-sectional views of the second pipe 122 and the third pipe 123 of the developer supply device 100A of FIG. 1, according to some example embodiments. The developer supply device 100A may include a developer storage container 111, a first pipe 121, a pump 131, a second pipe 122, a third pipe 123, a first flow rate controller 132, a second flow rate controller 133, a mixer 114, a fourth pipe 124, a first temperature sensor 141, a controller 150, and a nozzle 160.

The developer D1 may be stored in the developer storage container 111, and the developer storage container 111 may function as a supply source for the developer D1. The temperature of the developer D1 stored in the developer storage container 111 may be a room (or ambient) temperature (about 25° C.).

The first pipe 121 is fluidly connected to the developer storage container 111, and to the second pipe 122 and the third pipe 123 via the pump 131 and the developer D1 may be supplied from the developer storage container 111 to the second pipe 122 and the third pipe 123.

The pump 131 may be positioned on the first pipe 121 and may move the developer D1 from the upstream to the downstream of the first pipe 121. The position of the pump 131 within the first pipe 121 is not particularly limited, and the pump 131 may be installed on the upstream, the midstream, or the downstream of the first pipe 121, as desired by application and design.

In some example embodiments, the developer supply device 100A may further include a distributor for distributing the developer D1 to the second pipe 122 and the third pipe 123.

The second pipe 122 may supply a developer D2 having a first temperature. The third pipe 123 may supply a developer D3 having a second temperature lower than the first temperature. In some example embodiment, the first temperature is greater than about 55° C. and less than about 65° C. (e.g., approximately 60° C.) and/or the second temperature may be greater than 0° C. but less than about 10° C. (e.g., approximately 5° C.). For the sake of description, the developer D2 having the first temperature may be referred to as a high temperature developer D2, and the developer D3 having the second temperature may be referred to as a low temperature developer D3.

In some example embodiments, the second pipe 122 may be configured to change the temperature of the developer D1 (e.g., by heating the developer) to obtain a high temperature developer D2. In addition, in some example embodiments, the third pipe 123 may be configured to change the temperature of the developer D1 (e.g., by cooling the developer) to obtain a low temperature developer D3. It will be understood that developer D2 and developer D3 are both developer D1, but with one having a higher temperature than developer D1 and the other having a lower temperature than developer D1, respectively, and are referred to as developers D2 and D3 for the sake of explanation.

The second pipe 122 and the third pipe 123 may change the temperature of the developer D1 supplied from the same developer supply source (e.g., developer storage container 111) and provide the developers D2 and D3 with the different temperatures.

Referring to FIGS. 1, 2a, and 2b, in some example embodiments, the second pipe 122 may include a first inner pipe 1221 through which the developer D2 flows and a first outer pipe 1222 concentrically placed around the first inner pipe 1221 and through which a first fluid F1 flows. The third pipe 123 may include a second inner pipe 1231 through which the developer D3 flows, and a second outer pipe 1232 concentrically placed around the second inner pipe 1231 and through which a second fluid F2 having a lower temperature than the first fluid F1 flows. For example, water may be used as the first fluid F1 and the second fluid F2. However, example embodiments are not limited thereto, and any fluid that can provide the desired temperature control (as discussed herein) may be used as the first fluid F1 and the second fluid F2, without departing from the scope of the disclosure.

The developer supply device 100A may further include a first fluid container 112 that supplies the first fluid F1 to the first outer pipe 1222, and a second fluid container 113 that supplies the second fluid F2 to the second outer pipe 1232. Each of the first fluid container 112 and the second fluid container 113 may be equipped with a heater or a chiller (as desired), and each of these may keep the temperature of the first fluid F1 and the second fluid F2 around a desired temperature (e.g., a constant desired temperature). The first fluid F1 supplied through the first outer pipe 1222 and the second fluid F2 supplied through the second outer pipe 1232 may be circulated and returned to the first fluid container 112 and the second fluid container 113, respectively, and then reused, and may be transported to separate processing or storage devices.

The first pipe 121 is fluidly coupled to the first inner pipe 1221 of the second pipe 122 and the second inner pipe 1231 of the third pipe 123 so that the developer D1 may be supplied to the first inner pipe 1221 and the second inner pipe 1231. The developer D1 flowing in the first inner pipe 1221 may be heated by the first fluid F1, and the developer D1 flowing in the second inner pipe 1231 may be cooled by the second fluid F2. There may be a difference in the temperature (e.g., a temperature gradient) of the developers D2, D3 upstream and downstream of the first inner pipe 1221 and the second inner pipe 1231, respectively. For example, the temperature of the developers D2, D3 upstream of each of the respective first inner pipe 1221 and the second inner pipe 1231 may be the same or similar to the temperature of the developer D1 supplied into them. The temperature of the first fluid F1 may be about 55° C. to about 65° C. (e.g., approximately 60° C.) and/or the temperature of the second fluid F2 may be above 0° C. and below 10° C. (e.g., approximately 5° C.). However, the temperatures of the first fluid F1 and the second fluid F2 are not limited thereto, and may be increased or decreased as desired by application and/or design.

In other embodiments, the temperature of the first fluid F1 may be higher than the temperature of the second fluid F2, but may not be higher than the temperature of the developer D1. The first fluid F1 may therefore reduce the temperature of the developer D1 to a temperature higher than the low temperature developer D3. Similarly, the temperature of the second fluid F2 may be lower than the temperature of the first fluid F1, but may not be lower than the temperature of the developer D1. The second fluid F2 may therefore increase the temperature of the developer D1 to a temperature lower than the high temperature developer D2.

The first inner pipe 1221, the first outer pipe 1222, the second inner pipe 1231, and the second outer pipe 1232 may include a material such as a fluorine resin that may provide improved thermal insulation characteristics. In some example embodiments, the first inner pipe 1221, the first outer pipe 1222, the second inner pipe 1231, and the second outer pipe 1232 may be a perfluoroalkoxy (PFA) tube.

In some example embodiments, instead of a common developer source (or in addition to a common developer source), developers from separate (e.g., external) developer supply sources may be supplied to the second pipe 122 and the third pipe 123. For example, the high temperature developer D2 and the low temperature developer D3 may be supplied from separate (e.g., external) developer supply sources to the second pipe 122 and the third pipe 123, respectively. Alternatively or in addition, the second pipe 122 and the third pipe 123 may provide the high temperature developer D2 and the low temperature developer D3 by changing the temperature of the respective developer supplied from the separate developer supply sources.

The first flow rate controller 132 may control the flow rate of the high temperature developer D2 flowing into the mixer 114. The second flow rate controller 133 may control the flow rate of the low temperature developer D3 flowing into the mixer 114. In some example embodiments, each of the first flow rate controller 132 and the second flow rate controller 133 may be or include one or more flow rate control valves positioned downstream (or at the outlets) of the respective second pipe 122 and third pipe 123. The first flow rate controller 132 and the second flow rate controller 133 control the flow rates of the high temperature developer D2 and the low temperature developer D3, respectively, based on a control signal (or actuating signal) provided by a controller 150, which will be described later. Accordingly, flow rates of the high temperature developer D2 and the low temperature developer D3 flowing into the mixer 114 may be controlled. The controller 150 may be implemented in hardware, software or a combination of hardware and software. The controller 150 may be implemented using one or more general-purpose computers and special purpose computers such as, processors, controllers, arithmetic logic units (ALUs), digital signal processors, microcomputers, field programmable gate arrays (FPGAs), programmable logic units (PLUS), microprocessors, or any other device capable of executing and responding to instructions. The controller 150 may execute an Operating System (OS) and one or more software applications running on the operating system. In addition, the controller 150 may also access, store, manipulate, process, and generate data in response to execution of the computer readable code stored in a hardware memory device accessed by the controller 150.

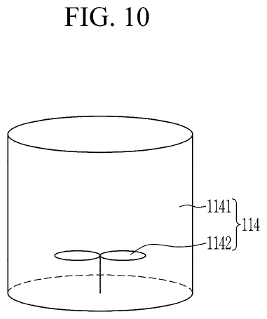

The mixer 114 may be fluidly coupled to the second pipe 122 and the third pipe 123, and provide a mixed developer D4 obtained by mixing the high temperature developer D2 and the low temperature developer D3. Since the flow rates of the high temperature developer D2 and the low temperature developer D3 can be controlled when provided to the mixer 114 for mixing, it is possible to adjust the mixing ratio of the high temperature developer D2 and the low temperature developer D3. As a result, the mixed developer D4 with a desired (or alternatively a predetermined) temperature may be obtained. Referring briefly to FIG. 10, the mixer 114 may include, for example, a container 1141 for holding the mixed developer D4 and a rotator 1142 for mixing the high temperature developer D2 and the low temperature developer D3 to obtain the mixed developer D4. The container 1141 may provide a space or volume for mixing the high temperature developer D2 and the low temperature developer D3, and have inlets for receiving the high temperature developer D2 and the low temperature developer D3 and one or more outlets for discharging the mixed developer D4. The rotator 1142 may blend, mix, and/or agitate the high temperature developer D2 and the low temperature developer D3 to obtain the mixed developer D4.

The temperature of the mixed developer D4 provided by the mixer 114 may be about 10° C. to about 55° C. In order to control the critical dimension (CD) and line edge roughness (LER) of the photoresist pattern developed using the mixed developer D4 and/or to control an angle formed between the photoresist pattern and the target substrate W within the appropriate range, it may be advisable to adjust the temperature of the mixed developer D4. For instance, temperature may be adjusted to the above-mentioned range.

Returning to FIGS. 1, 2a, and 2b, the fourth pipe 124 may be connected to the mixer 114 and the nozzle 160, and the mixed developer D4 may be supplied from mixer 114 to nozzle 160 for dispensing the mixed developer D4 on the target substrate W. To maintain the temperature of the mixed developer D4 at a desired (or alternatively predetermined) temperature, the fourth pipe 124 may be an insulated pipe. As it may be desired to maintain the temperature of the mixed developer D4 after flowing out of the mixer 114, the fourth pipe 124 can be configured as a single pipe.

The developer supply device 100A may further include a third flow rate controller 134 that controls the flow rate of the mixed developer D4 flowing out of the mixer 114. The third flow rate controller 134 may be or include a flow rate control valve positioned in the fourth pipe 124, for example, at a location upstream of the fourth pipe 124. The high temperature developer D2 and the low temperature developer D3 may inflow into the mixer 114 with the flow rates controlled by the first flow rate controller 132 and the second flow rate controller 133, respectively, and the flow rate of the mixed developer D4 may be changed depending on various factors such as the flow rate of the high temperature developer D2 and the low temperature developer D3, the mixing ratio, and/or the rotation speed of the rotating machine (e.g., the machine rotating the target substrate W when the developer is being dispensed on the substrate W). The third flow rate controller 134 may control a flow of the mixed developer D4 such that the mixed developer D4 may be provided to with an appropriate (or desired) and/or constant flow rate to the nozzle 160 for dispensing on the target substrate W.

The first temperature sensor 141 may measure the temperature of the mixed developer D4. The temperature measured by the first temperature sensor 141 may be transmitted to the controller 150 (e.g., via signal line 151) and may be used as a feedback data for adjusting the temperature of the mixed developer D4.

The controller 150 may control the first flow rate controller 132 and/or the second flow rate controller 133 based on the temperature measured by the first temperature sensor 141. The controller 150 controls the first flow rate controller 132 and/or the second flow rate controller 133 to control the flow rate of the high temperature developer D2 and/or the low temperature developer D3 that flow into the mixer 114, thereby controlling the temperature of the mixed developer D4 by controlling the mixing ratio of the high temperature developer D2 and the low temperature developer D3. In some example embodiments, the controller 150 may implement a PID control method for controlling the flow rate.

The controller 150 may compare the temperature of the mixed developer D4 measured by the first temperature sensor 141 with a predetermined (or desired) temperature (e.g., a temperature desired a user) and may calculate the difference value. Depending on the difference value, the controller 150 may change the flow rates of the high temperature developer D2 and/or the low temperature developer D3. For example, if the temperature of the mixed developer D4 measured by the first temperature sensor 141 is lower than the predetermined or desired temperature, the controller 150 may increase the flow rate of the high temperature developer D2 flowing through the first flow rate controller 132 and/or decrease the flow rate of the low temperature developer D3 flowing through the second flow rate controller 133. Alternatively, when the temperature of the mixed developer D4 measured by the first temperature sensor 141 is higher than the predetermined or desired temperature, the controller 150 may reduce the flow rate of the high temperature developer D2 flowing through the first flow rate controller 132 and/or increase the flow rate of the low temperature developer D3 flowing through the second flow rate controller 133. In some example embodiments, an amount by which the flow rate of the high temperature developer D2 is changed and an amount by which the flow rate of the low temperature developer D3 is changed may be the same. In other words, the flow rate of the low temperature developer D3 may decrease (or increase) by a same amount as the flow rate of the high temperature developer D2 is increased (or decreased). Therefore, the total flow rate of the high temperature developer D2 and the low temperature developer D3 may be maintained at a constant value.

The nozzle 160 may dispense the mixed developer D4 provided from the mixer 114 onto the target substrate W. The nozzle 160 may move on the target substrate W, and the dispensing position of the mixed developer D4 may be adjusted. Additionally or alternatively, the nozzle 160 may be stationary and the target substrate W may be rotated at a desired rotational speed while the mixed developer D4 is being dispensed in order to spread the mixed developer D4 on the target substrate W.

Since the pattern of the photoresist is sensitive to the temperature of the developer, it is desirable to control the temperature of the developer dispensed on the wafer. For example, the temperature of the developer may affect the critical dimension (CD) and/or the line edge roughness (LER) of the pattern, and the angle between the pattern and the target substrate, which may be factors in controlling the exposure dose when developing the photoresist. Additionally, the optimal developer temperature for the photoresist development may vary depending on the type of the photoresist. Therefore, it is desirable to accurately adjust the temperature of the developer in a relatively short time based on the type of developer being used, the number of layers of developer dispensed on the wafer W, the time for which the developer is exposed to radiation during development, and the like.

According to some example embodiments, by mixing the high temperature developer D2 and the low temperature developer D3 using the mixer 114, the mixed developer D4 of a desired or predetermined temperature may be obtained. By measuring the temperature value of the mixed developer D4 adjacent to the nozzle 160 prior to dispensing and controlling the flow rates of the high temperature developer D2 and/or the low temperature developer D3 based on the measured temperature, the temperature of the mixed developer D4 may be controlled with increased accuracy and in real-time (or near real-time).

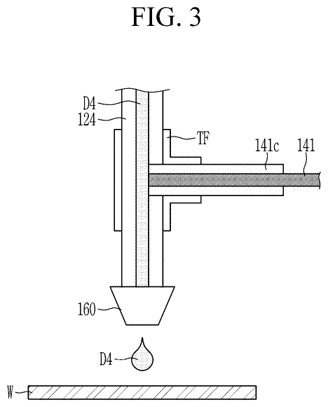

FIG. 3 illustrates the first temperature sensor 141 included in the developer supply device 100A of FIG. 1, according to some example embodiments.

The first temperature sensor 141 may measure the temperature of the mixed developer D4 in the fourth pipe 124. The first temperature sensor 141 may be, for example, a contact-type temperature sensor that may measure the temperature of the mixed developer D4 by contacting the mixed developer D4. In some example embodiments, the first temperature sensor 141 may be or include a thermocouple, thermistor, resistance temperature detector, or the like. The first temperature sensor 141 may include a tube-shaped coating layer (or a sheath or covering) 141C to protect the first temperature sensor 141. Additionally, the fourth pipe 124 and the first temperature sensor 141 may be connected to each other by a T-shaped fitting member TF. As illustrated, the first temperature sensor 141 is positioned transverse to the flow of the mixed developer D4 in the fourth pipe 124 and contacts the mixed developer D4. The T-shaped fitting member TF may secure the first temperature sensor 141 in position so that the first temperature sensor 141 and the mixed developer D4 maintain contact and the measurement provided by the first temperature sensor 141 may be considered reliable. The first temperature sensor 141 may be coupled to the fourth pipe 124 proximate the nozzle 160 so that the temperature of the mixed developer D4 as measured in the fourth pipe 124 may be the same as or close to (e.g., +/−1° C.) the temperature of the mixed developer D4 being dispensed from the nozzle 160.

A contact-type temperature sensor provides a relatively faster response time when measuring the temperature of the mixed developer D4 and in a cost effective way.

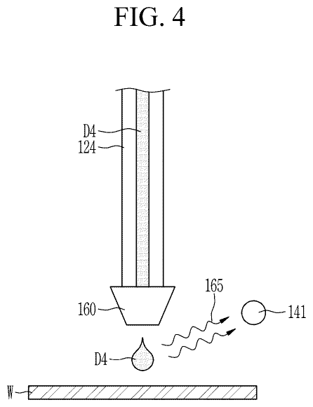

FIG. 4 illustrates the first temperature sensor 141 included in the developer supply device 100A of FIG. 1, according to some example embodiments.

The first temperature sensor 141 may be, for example, a non-contact temperature sensor that measures the temperature without being in contact with the mixed developer D4. The first temperature sensor 141 as a non-contact temperature sensor may detect temperature changes based on optical analysis of radiation 165 (e.g., infrared radiation) generated by the mixed developer D4. In some example embodiments, the first temperature sensor 141 may be or include optical pyrometers, radiation thermometers, thermal imagers, fiber optic sensors, and the like. Since there is no contact between the mixed developer D4 and the first temperature sensor 141, contamination (e.g., due to particles that may be dislodged or separated from the first temperature sensor 141) of the mixed developer D4 is reduced, prevented, or minimized. As a result, the temperature measured may be more accurately. In addition, a more accurate feedback data (e.g., generated by measuring the temperature of the mixed developer D4) is provided to the controller 150. In an example, and as illustrated, the first temperature sensor 141 may measure the temperature of the mixed developer D4 after the mixed developer D4 has been dispensed from the nozzle 160 (e.g., exited the fourth pipe 124) and/or the first temperature sensor 141 may measure the temperature of the mixed developer D4 after the mixed developer D4 has been deposited on the target substrate W.

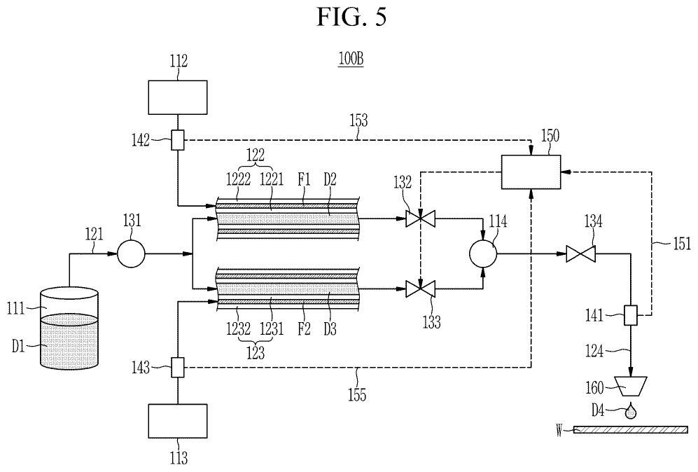

FIG. 5 illustrates a developer supply device 100B, according to some example embodiments. The developer supply device 100B may be similar in some respects to the developer supply device 100A of FIG. 1, and therefore may be best understood with reference thereto where like numerals indicate like elements not described again in detail.

The developer supply device 100B may further include a second temperature sensor 142 that measures the temperature of the first fluid F1 flowing out of the first fluid container 112 and a third temperature sensor 143 that measures the temperature of the second fluid F2 flowing out of the second fluid container 113. The second temperature sensor 142 and/or the third temperature sensor 143 may be similar to the first temperature sensor 141. For instance, the second temperature sensor 142 and/or the third temperature sensor 143 may be a contact-type temperature sensor or a non-contact temperature sensor, as discussed above. The controller 150 may control the first flow rate controller 132 and/or the second flow rate controller 133 based on the temperatures measured by the second temperature sensor 142 and/or the third temperature sensor 143.

The temperature values measured by the second temperature sensor 142 and/or the third temperature sensor 143 are transmitted to the controller 150 via signal lines 153 and 155, respectively, and may be used by the controller 150 as a feedforward data to determine the temperature of mixed developer D4. Thus, the developer supply device 100B receives not only the feedback data via signal line 151, but also a feedforward data to control the flow rate of the high temperature developer D2 and/or the low temperature developer D3, and thereby controls the temperature of the mixed developer D4 accurately and in a relatively short time.

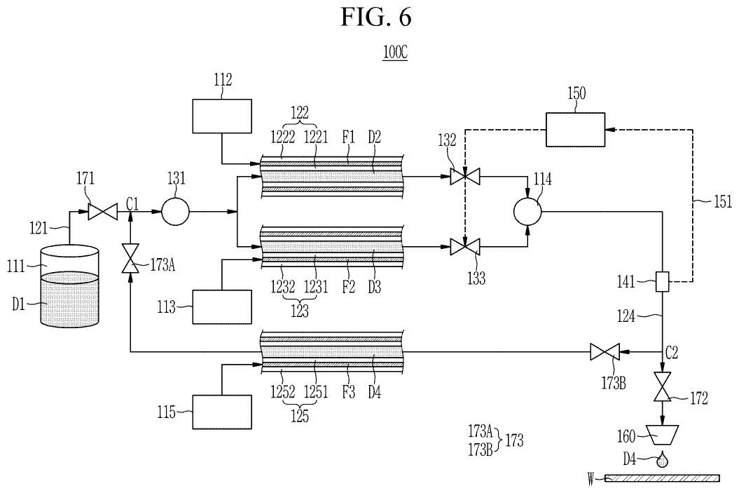

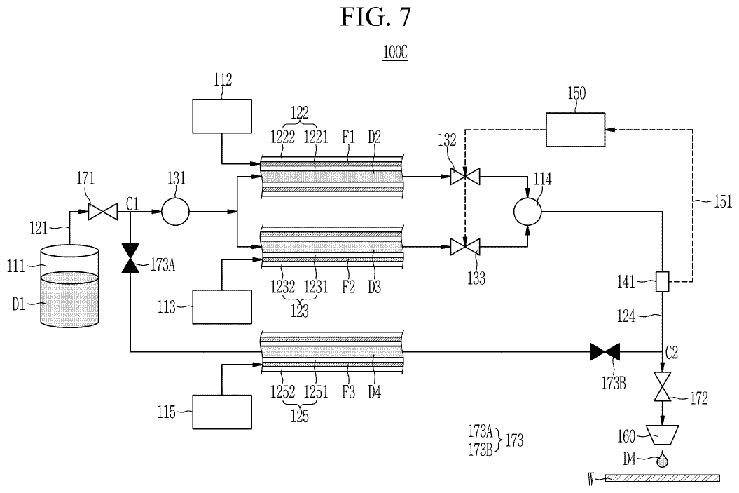

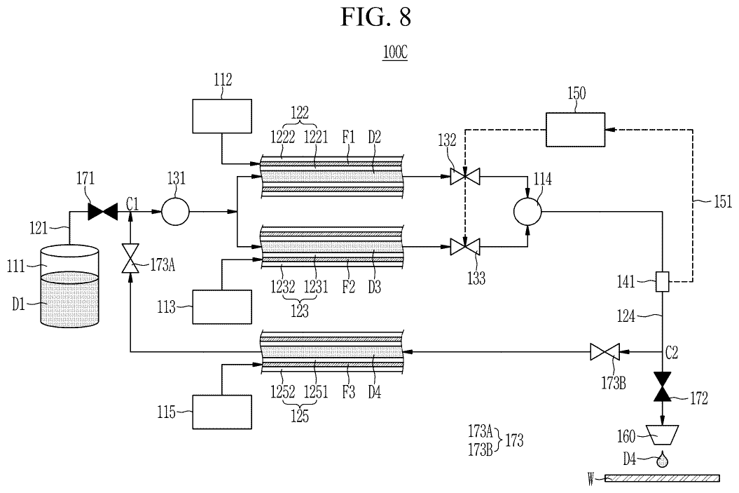

FIG. 6 illustrates a developer supply device 100C, according to some example embodiments. FIG. 7 illustrates a developer flow path in the developer supply device 100C of FIG. 6 when dispensing the mixed developer, according to some example embodiments. FIG. 8 illustrates a developer flow path in the developer supply device 100C of FIG. 6 when a mixed developer is not dispensed, according to some example embodiments. The developer supply device 100C may be similar in some respects to the developer supply device 100A of FIG. 1, and therefore may be best understood with reference thereto where like numerals indicate like elements not described again in detail.

The developer supply device 100C may further include a fifth pipe 125, a first block valve 171, a second block valve 172, and third block valves 173A and 173B (collectively referred to as third block valves 173) that may implement a circulation system in which the mixed developer D4 may flow when the developer D1 is not being dispensed.

The fifth pipe 125 may be connected to the fourth pipe 124 and the first pipe 121, so that the mixed developer D4 may be supplied from the fourth pipe 124 to the first pipe 121 when developer dispensing is turned off. The fifth pipe 125 may be similar in some respects to the second pipe 122 and the third pipe 123. The fifth pipe 125 may include a third inner pipe 1251 through which the mixed developer D4 flows and a third outer pipe 1252 positioned concentrically around the third inner pipe 1251 and through which the third fluid F3 flows.

The developer supply device 100C may further include a third fluid container 115 that supplies the third fluid F3 to the third outer pipe 1252. For example, the third fluid F3 may be water (or any other suitable fluid), and the third fluid F3 may be at room (or ambient) temperature. Therefore, the third fluid container 115 may not be equipped with a heater or chiller. Using the third fluid F3, the temperature of the mixed developer D4 may be restored to an initial condition (e.g., a room temperature).

The mixed developer D4 may be selectively supplied from the fourth pipe 124 to the nozzle 160 or the fifth pipe 125. For example, the mixed developer D4 may be supplied from the fourth pipe 124 to the nozzle 160 during the dispensing, and from the fourth pipe 124 to the fifth pipe 125 while the dispensing is turned off.

The first block valve 171 may be positioned in the first pipe 121. For example, the first block valve 171 may be positioned between a junction C1 where the fifth pipe 125 is connected to the first pipe 121 and the developer storage container 111. The junction C1 is located downstream from the first block valve 171.

The second block valve 172 may be positioned in the fourth pipe 124. For example, the second block valve 172 may be positioned between a junction C2 where the fifth pipe 125 and the fourth pipe 124 are connected, and the nozzle 160.

The third block valves 173 may be positioned in the fifth pipe 125. The third block valve 173A may be positioned downstream from the fifth pipe 125 and adjacent to the first pipe 121, and may be fluidly coupled to the junction C1. The third block valve 173B may be positioned upstream of the fifth pipe 125 and adjacent to the fourth pipe 124, and may be fluidly coupled to the junction C2. When dispensing the mixed developer D4, the third block valve 173A may reduce, minimize, or prevent the inflow of the mixed developer D4 from the first pipe 121 to the fifth pipe 125, and the third block valve 173B may reduce, minimize, or prevent the flow of the mixed developer D4 from the fourth pipe 124 to the fifth pipe 125.

Selectively turning ON/OFF one or more of the first block valve 171, the second block valve 172, and the third block valves 173A, 173B may allow or impede flow of the mixed developer D4 in the developer supply device 100C. The flow of the mixed developer D4 may be controlled using the combination of the first block valve 171, the second block valve 172, and the third block valves 173A, 173B.

Referring to FIG. 7, when dispensing the mixed developer D4, the first block valve 171 and the second block valve 172 may be opened, and the third block valves 173A and 173B may be closed. Therefore, when dispensing, the mixed developer D4 may be supplied from the developer storage container 111 to the nozzle 160.

On the other hand, referring to FIG. 8, when the mixed developer D4 is to be blocked from exiting the nozzle 160, the first block valve 171 and the second block valve 172 may be closed, and the third block valves 173A, 173B may be opened. As a result, the mixed developer D4 is blocked from exiting the nozzle 160, and the mixed developer D4 may circulate in the flow path including the fifth pipe 125, the first pipe 121, the second pipe 122, the third pipe 123, and the fourth pipe 124.

Since the mixed developer D4 circulates in the pipes even when dispensing is turned off, transient response when the mixed developer D4 dispensing is turned on and off is reduced or minimized. In addition, a temperature hunting phenomenon in which the temperature of the mixed developer D4 goes higher than or lower than the predetermined or desired temperature is also reduced or minimized.

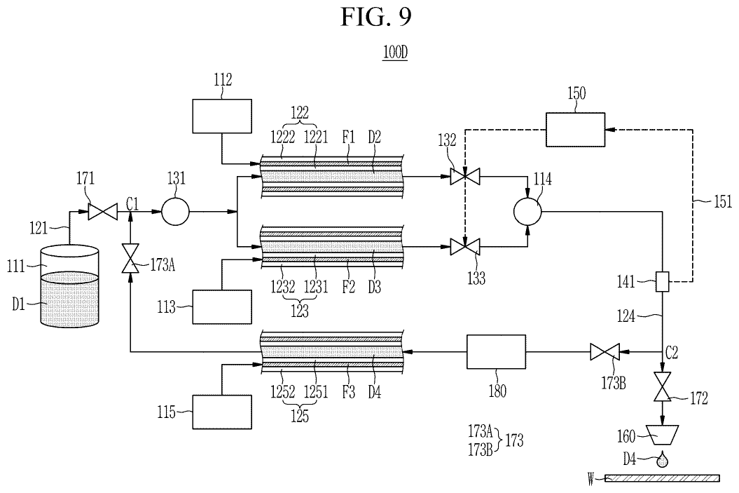

FIG. 9 illustrates a developer supply device 100D, according to some example embodiments. The developer supply device 100D may be similar in some respects to the developer supply device 100C of FIG. 6, and therefore may be best understood with reference thereto where like numerals indicate like elements not described again in detail.

The developer supply device 100D may further include a filter 180 positioned in the fifth pipe 125. The filter 180 may filter the mixed developer D4 and reduce, minimize or prevent contaminants from flowing into and thereby accumulating in the pipes 121, 122, 123, 124, and 125.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A developer supply device, comprising:
a first pipe configured to supply a developer having a first temperature;
a second pipe configured to supply the developer having a second temperature lower than the first temperature;
a mixer fluidly connected to the first pipe and the second pipe and configured to mix the developer having the first temperature and the developer having the second temperature to obtain a mixed developer;
a first flow rate controller configured to control a flow rate of the developer having the first temperature flowing into the mixer;
a second flow rate controller configured to control a flow rate of the developer having the second temperature flowing into the mixer;
a nozzle configured to dispense the mixed developer from the mixer on a target substrate;
a third pipe fluidly connected to the mixer and the nozzle and configured to supply the mixed developer from the mixer to the nozzle;
a temperature sensor configured to measure a temperature of the mixed developer; and
a controller configured to control the first flow rate controller, the second flow rate controller, or both the first flow rate controller and the second flow rate controller based on the temperature of the mixed developer measured by the temperature sensor.

2. The developer supply device of claim 1, further comprising:
a third flow rate controller configured to control a flow rate of the mixed developer flowing out of the mixer.

3. The developer supply device of claim 1, wherein:
the temperature sensor is configured to measure the temperature of the mixed developer in the third pipe.

4. The developer supply device of claim 3, wherein:
the temperature sensor is a contact-type temperature sensor.

5. The developer supply device of claim 1, wherein:
the temperature sensor is configured to measure the temperature of the mixed developer dispensed from the nozzle.

6. The developer supply device of claim 5, wherein:
the temperature sensor is a non-contact-type temperature sensor.

7. The developer supply device of claim 1, wherein:
the temperature of the mixed developer is 10° C. to 55° C.

8. The developer supply device of claim 1, wherein:
the first flow rate controller and the second flow rate controller are configured as flow rate control valves positioned in the first pipe and the second pipe, respectively.

9. The developer supply device of claim 1, wherein:
the mixer includes a receiving container configured to accommodate the mixed developer and a rotator that is configured to mix the mixed developer.

10. A developer supply device, comprising:
a first pipe configured to supply a developer having a first temperature, the first pipe including a first inner pipe through which the developer flows and a first outer pipe positioned concentric with the first inner pipe and through which a first fluid flows;
a second pipe configured to supply a developer having a second temperature lower than the first temperature, the second pipe including a second inner pipe through which the developer flows and a second outer pipe positioned concentric with the second inner pipe and through which a second fluid having a temperature lower than the first fluid flows;
a mixer fluidly connected to the first pipe and the second pipe and configured to mix the developer having the first temperature and the developer having the second temperature to obtain a mixed developer;
a first flow rate controller configured to control a flow rate of the developer having the first temperature flowing into the mixer;
a second flow rate controller configured to control a flow rate of the developer having the second temperature flowing into the mixer;
a nozzle configured to dispense the mixed developer from the mixer on a target substrate;
a third pipe fluidly connected to the mixer and the nozzle, and configured to supply the mixed developer from the mixer to the nozzle;
a first temperature sensor configured to measure a temperature of the mixed developer; and
a controller configured to control the first flow rate controller, the second flow rate controller, or both the first flow rate controller and the second flow rate controller based on the temperature of the mixed developer measured by the first temperature sensor.

11. The developer supply device of claim 10, further comprising:
a first fluid container configured to supply the first fluid to the first outer pipe; and
a second fluid container configured to supply the second fluid to the second outer pipe.

12. The developer supply device of claim 11, further comprising:
a second temperature sensor configured to measure a temperature of the first fluid flowing out of the first fluid container; and
a third temperature sensor configured to measure a temperature of the second fluid flowing out of the second fluid container,
wherein the controller is configured to control the first flow rate controller, the second flow rate controller, or both the first flow rate controller and the second flow rate controller based on the temperature of the first fluid and the temperature of the second fluid.

13. The developer supply device of claim 10, further comprising:
a developer storage container configured to store the developer; and
a third pipe fluidly connected to the developer storage container, the first inner pipe and the second inner pipe, and configured to supply the developer to the first inner pipe and the second inner pipe from the developer storage container.

14. The developer supply device of claim 13, further comprising:
a pump positioned in the third pipe.

15. The developer supply device of claim 10, wherein:
at least one of the first inner pipe, the first outer pipe, the second inner pipe, and the second outer pipe include a fluorine resin.

16. A developer supply device, comprising:
a developer storage container configured to store a developer;
a first pipe configured to change a temperature of the developer and configured to supply the developer having a first temperature;
a second pipe configured to change the temperature of the developer and configured to supply the developer having a second temperature lower than the first temperature;
a third pipe fluidly connected to the developer storage container, the first pipe and the second pipe, and configured to supply the developer from the developer storage container to the first pipe and the second pipe;
a mixer fluidly connected to the first pipe and the second pipe and configured to mix the developer having the first temperature and the developer having the second temperature to obtain a mixed developer;
a first flow rate controller configured to control a flow rate of the developer having the first temperature flowing into the mixer;
a second flow rate controller configured to control a flow rate of the developer having the second temperature flowing into the mixer;
a nozzle configured to dispense the mixed developer provided from the mixer on a target substrate;
a fourth pipe fluidly connected to the mixer and the nozzle and configured to supply the mixed developer from the mixer to the nozzle;
a fifth pipe fluidly connected to the fourth pipe and the third pipe, and configured to supply the mixed developer from the fourth pipe to the third pipe when the mixed developer is not dispensed;
a temperature sensor configured to measure a temperature of the mixed developer; and
a controller configured to control the first flow rate controller, the second flow rate controller, or both the first flow rate controller and the second flow rate controller based on the temperature of the mixed developer measured by the temperature sensor,
wherein, when the mixed developer is not being dispensed, the first pipe, the second pipe, the third pipe, the fourth pipe, and the fifth pipe are configured to circulate the mixed developer.

17. The developer supply device of claim 16, further comprising:
a first block valve positioned between (1) a junction of the third pipe and the fifth pipe, and (2) the developer storage container;
a second block valve positioned between a (1) junction of the fourth pipe and the fifth pipe, and (2) the nozzle; and
at least one third block valve positioned in the fifth pipe, wherein
the first block valve and the second block valve are opened when the mixed developer is dispensed and closed when the mixed developer is not dispensed, and
the at least one third block valve is closed when the mixed developer is dispensed, and opened when the mixed developer is not dispensed.

18. The developer supply device of claim 17, wherein:
the at least one third block valve includes a first valve positioned adjacent to the third pipe and a second valve positioned adjacent to the fourth pipe.

19. The developer supply device of claim 16, further comprising:
a filter positioned in the fifth pipe.

20. The developer supply device of claim 16, wherein:
the fifth pipe includes an inner pipe that is configured to carry the mixed developer and an outer pipe positioned concentrically around the inner pipe and configured to carry a fluid.
